(19) United States
(12) Patent Application Publication
(10) Pub. No.: US 2011/0080709 A1
(43) Pub. Date: Apr. 7, 2011

(54) Digital Signage Player

(76) Inventor: Tony Lin, Taipei (TW)

(21) Appl. No.: 12/652,038

(22) Filed: Jan. 5, 2010

(30) Foreign Application Priority Data
Oct. 5, 2009 (TW) 098218311

(51) Int. Cl. H05K 7/20

(52) U.S. Cl. 361/697; 361/703

(57) ABSTRACT

A digital signage player is provided. The digital signage player includes a body having a main board and a hard disk, an outer frame in which the body is framed, and a heat dissipation unit disposed in the body. The digital signage player of the present invention can be conveniently fixed to a wall surface nearby the digital signage by fixing a fixing mechanism of the outer frame with screw bolts or rivets to the wall surface. Further, the corrugation shaped heat dissipation fins are also configured to prevent dusts or dirts from entering the body and contaminating the main board.

### BACKGROUND OF THE INVENTION

1. Field of the Invention

The present invention relates generally to a digital player, and more particularly, to a digital player having a dust-proof and heat dissipation device and being specifically adapted for a digital signage.

2. The Prior Arts

Recent investigations indicate that a large number of consumers would be affected by the promotion information advertised by digital signage settled in stores, and their consumer behaviors are likely to be influenced. Correspondingly, electronic digital signage, characterized in providing dynamic and integral information, chart, and cartoon, has been widely employed in public sites, such as bus stations, air ports, and shopping malls. Generally, a digital signage can be used for broadcasting information, promoting corporation image, and enhancing awareness of brands, and stimulating the desire to buy. Therefore, the digital signage market is being fast developed.

A conventional digital signage can be played by simply externally coupling a DVD player thereto. However, some digital signages are to be installed outdoors or in large public spaces, where the environmental conditions are usually inferior to typical home condition. For example, such a signage may be exposed to more dust or perspiration. Further, a conventional externally coupled digital player may breakdown when it suffers excessive heat. Furthermore, the digital player externally coupled to the digital signage may have to be settled on a supporter, which should usually be additionally prepared by the customer himself. Conventional digital signages are also often very large, so that the installation and adjustment are complicated and inconvenient.

### SUMMARY OF THE INVENTION

A primary objective of the present invention is to provide digital signage player, which is slim and light, portable and convenient for installation. The digital signage player is particularly adapted for a digital signage, and is also featured with heat dissipation device having an improved dust-proof performance.

For achieving the foregoing objective and other, the present invention provides a digital signage player. The digital signage player includes a body, an outer frame, and a heat dissipation unit.

The body includes an enclosure and a substrate. The enclosure is covered upon the substrate, thus defining a space of the body therebetween. The body further includes a main board and a hard disk disposed in the space.

The body is framed inside the outer frame and is secured thereto, and the outer frame includes at least one fixing mechanism.

The heat dissipation unit is disposed in the body, and includes at least one fan, and heat dissipation fins. The heat dissipation fins are corrugation shaped and positioned opposite to the fan on one side of the main board.

Accordingly, when a user desires to secure the digital signage player of the present invention to a wall surface nearby the digital signage, the user can fix the fixing mechanism of the outer frame securing the body therein to the wall surface with screw bolt or rivet.

When the main board and the hard disk are in operation, they generate heat. The heat is then transferred from the main board via the substrate to the heat dissipation fins. The fan of the heat dissipation unit guides outside cold air inwardly blowing on one end of the heat dissipation fins, and the cold air flows through gaps of corrugation shaped heat dissipation fins, thus dissipating the heat out of the body from another end of the heat dissipation fins. In addition to the heat dissipation function, the corrugation shaped heat dissipation fins are employed thereby for preventing dusts or dirts from entering the body and contaminating the main board.

### BRIEF DESCRIPTION OF THE DRAWINGS

The present invention will be apparent to those skilled in the art by reading the following detailed description of preferred embodiments thereof, with reference to the attached drawings, in which:

FIG. 1 is a perspective view of a digital signage player according to an embodiment of the present invention;

FIG. 2 is an exploded view of the digital signage player according to an embodiment of the present invention;

FIG. 3 is an assembled view of the digital signage player of the present invention; and

FIG. 4 is a schematic drawing illustrating the status of use of the digital signage player of the present invention.

### DETAILED DESCRIPTION OF THE PREFERRED EMBODIMENT

The accompanying drawings are included to provide a further understanding of the invention, and are incorporated in and constitute a part of this specification. The drawing illustrates embodiments of the invention and, together with the description, serves to explain the principles of the invention.

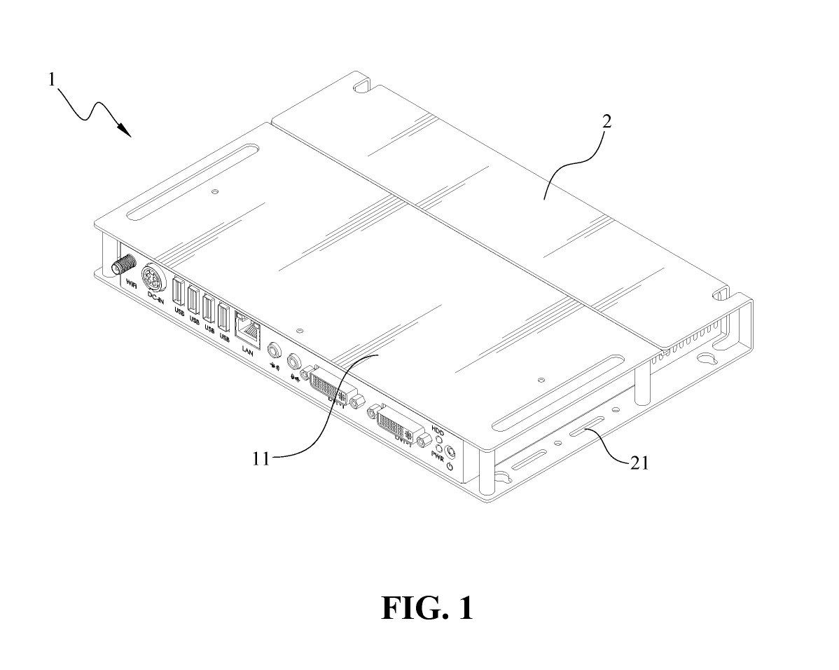

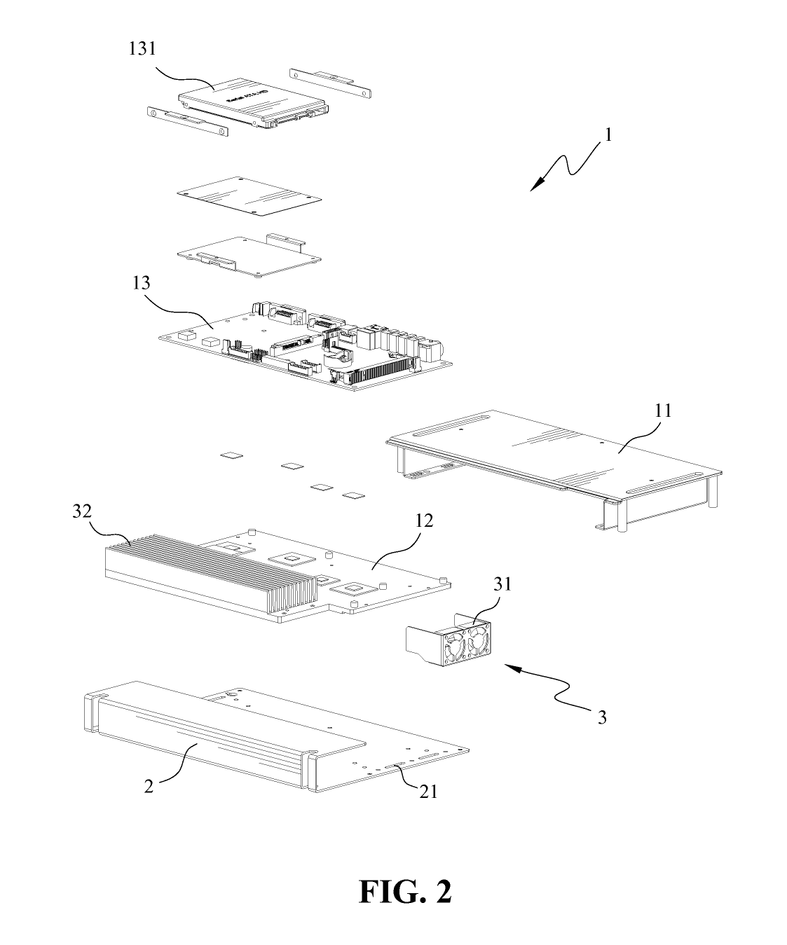

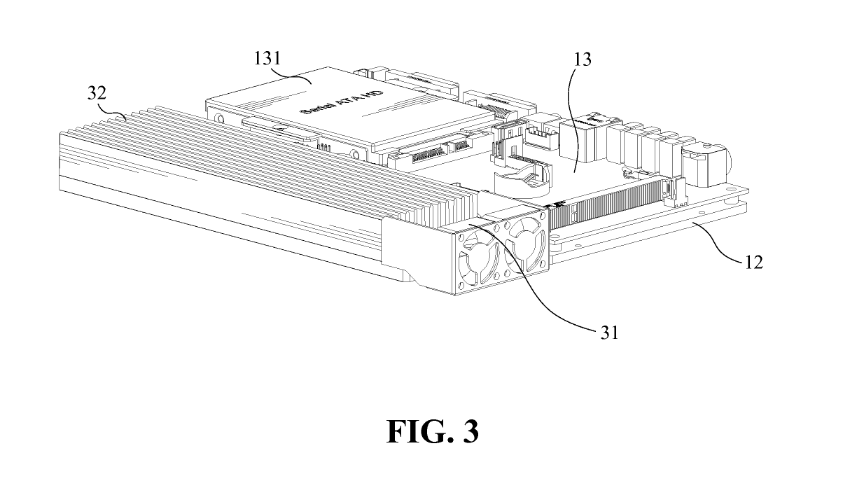

FIG. 1 is a perspective view of the digital signage player according to an embodiment of the present invention. FIG. 2 is an exploded view of the digital signage player according to an embodiment of the present invention. FIG. 3 is an assembled view of the digital signage player of the present invention. Referring to FIGS. 1 through 3, there is shown a digital signage player.

The digital signage player includes a body 1, an outer frame 2, and a heat dissipation unit 3.

The body 1 includes an enclosure 11 and a substrate 12. The enclosure 11 is covered upon the substrate 12, thus defining a space of the body 1 therebetween. The body 1 further includes a main board 13 and a hard disk 131 disposed in the space.

The body 1 is framed inside the outer frame 2 and is secured thereto, and the outer frame 2 includes at least one fixing mechanism 21 disposed at one side of the outer frame 2. Preferably, the fixing mechanism 21 is a screw hole.

The heat dissipation unit 3 is disposed in the body 1, and includes at least one fan 31, and heat dissipation fins 32. The heat dissipation fins 32 are corrugation shaped and positioned on one side of the main board 13. The fan 31 and the heat dissipation fins 32 are disposed at opposite sides of the main board 13. Preferably, the fan 31 is a magnetic bearing fan.

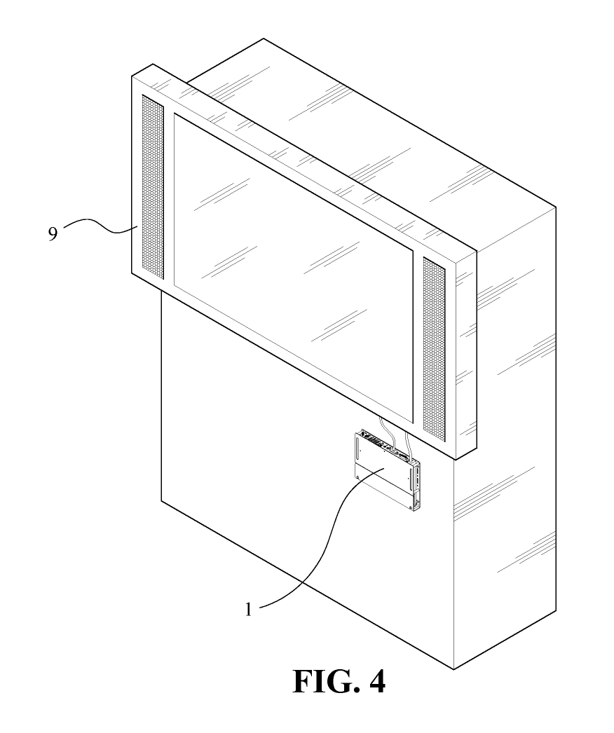

FIG. 4 is a schematic drawing illustrating the status of use of the digital signage player of the present invention. Referring to FIG. 4, when a user intends to install the digital signage player of the present invention on a wall surface nearby a digital signage 9, the user can use fixing members, such as screw bolts or rivets, to fix the fixing mechanism 21 of the outer frame 2, to which the body 1 is secured. In such a way, the digital signage player of the present invention can be conveniently fixed to the wall surface. Alternatively, the user is also allowed to fix the fixing mechanism 21 to a backside of a casing of the digital signage 9, so as to secure the digital signage player of the present invention at the backside of the digital signage 9.

Furthermore, it should be noted that the digital signage player of the present invention can also be modified to serve for many other media, such as an LED marquee, an ordinary computer, a television screen, or a projector.

Referring to FIG. 3 again, when the digital signage player of the present invention is installed, and electrically coupled to the digital signage, the digital signage player can be then played for displaying digital images on the digital signage 9. Meanwhile, the main board 13 and the hard disk 131 are in operation while generating heat. The heat is then transferred from the main board 13 via the substrate 13 to the heat dissipation fins 32. The fan 31 of the heat dissipation unit 3 guides outside cold air inwardly blowing on one end of the heat dissipation fins 32, and the cold air flows through gaps of corrugation shaped heat dissipation fins 32, thus dissipating the heat out of the body 1 from another end of the heat dissipation fins 32. In addition to the heat dissipation function, the corrugation shaped heat dissipation fins 32 are employed thereby for also preventing dusts or dirts from entering the body 1 and contaminating the main board 13.

The digital signage player of the present invention is slim and light, portable and convenient for installation. The heat dissipation unit 3 is also featured in preventing dusts or dirts from entering the body 1 and contaminating the main board 13, and thus the digital signage player is specifically suitable for outdoor environment. The outer frame 2 allows the user to conveniently fix the digital signage player nearby the digital signage 9 without further preparing additional tools or parts.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A digital signage player, comprising:
a body, comprising an enclosure, a substrate, a main board, and a hard disk, wherein the enclosure is covered upon the substrate, and defines a space of the body between the enclosure and the substrate, and the main board and the hard disk are disposed in the space; and
a heat dissipation unit, disposed in the body, wherein the heat dissipation unit comprises at least one fan, and a plurality of heat dissipation fins, wherein the heat dissipation fins are corrugation shaped and positioned at one side of the main board, and the fan is positioned opposite to the heat dissipation fins.

2. The digital signage player according to claim 1, wherein the body is framed inside an outer frame, and the outer frame comprises at least one fixing mechanism at one side of the outer frame.

3. The digital signage player according to claim 2, wherein the fixing mechanism is a screw hole.

4. The digital signage player according to claim 1, wherein the fan is a magnetic bearing fan.
